(19) United States
(12) Patent Application Publication
(10) Pub. No.: US 2025/0350211 A1
(43) Pub. Date: Nov. 13, 2025

(54) ELECTRIC COMPRESSOR

(71) Applicants: Hanon Systems, Daejeon (KR); DAEYOUNG ELECTRONICS CO.,LTD, Gyeongsangbuk-do (KR)

(72) Inventors: Hyun Woo LEE, Daejeon (KR); Tae Ei RYU, Gyeonggi-do (KR); Young Hyun LEE, Gyeonggi-do (KR); Do Won LIM, Daegu (KR); Seung Kil KIM, Daejeon (KR); Sung Taeg OH, Daejeon (KR); Young Seop YOON, Daejeon (KR); Seung Yong HWANG, Daejeon (KR)

(21) Appl. No.: 19/204,823

(22) Filed: May 12, 2025

(30) Foreign Application Priority Data
May 10, 2024 (KR) 1020240061787

(51) Int. Cl. H02M 7/00; H05K 7/14

(52) U.S. Cl. CPC H02M 7/003; H05K 7/1427

(57) ABSTRACT

An electric compressor, including: a housing; a compression part to compress a refrigerant introduced into the housing; a motor part provided in the housing to drive the compression part; and an inverter part provided on one side of the housing to control the motor part, the inverter part may include: an inverter cover coupled to one side of the housing; an inverter body fixed inside the inverter cover; and a circuit board seated on the inverter body and allowing one or more elements to be disposed on one surface thereof facing the housing, the inverter body may include: one or more boss portions protruding from a base surface toward the circuit board, and a pressing member may be inserted into at least one among the one or more boss portions and the pressing member presses another surface which is an opposite side of the one surface of the circuit board.

### CROSS REFERENCE TO RELATED APPLICATION

This patent application claims the benefit of and priority to Korean Patent Application No. KR 10-2024-0061787 filed on May 10, 2024, the entire contents of which are incorporated herein by reference for all purposes.

### FIELD

The present disclosure relates to an electric compressor, more particularly, to an electric compressor of which an inverter cover, an inverter body and a circuit board can be modularized, and capable of improving contactability between a switching element and a motor housing by allowing a pressing member inserted into a boss portion of the inverter body to press another surface, which is an opposite side of one surface on which a switching element of the circuit board is disposed.

### BACKGROUND

Generally, air conditioning (A/C) apparatuses for cooling or heating passenger compartments are installed in vehicles. Such an air conditioning apparatus includes a compressor, which compresses low-temperature and low-pressure gaseous refrigerant drawn from an evaporator into a high-temperature and high-pressure gaseous state, and transfers it to a condenser.

Compressors applied to such vehicles include a mechanical compressor that is driven by receiving the driving force of the engine and an electric compressor that uses a motor driven by electricity, and in recent years, the use of electric compressors has increased as the vehicle electrification has been accelerated.

Meanwhile, examples of the compressor include a reciprocating compressor that compresses a refrigerant according to which pistons reciprocate, and a rotary compressor that compresses a refrigerant while rotating. The reciprocating compressor includes a crank compressor that transmits a driving force from a drive source to a plurality of pistons using a crank, a swash plate compressor that transmits a driving force from a drive source to a shaft installed with a swash plate, and the like, according to the power transmission from the drive source. The rotary compressor includes a vane rotary compressor that utilizes a rotating rotary shaft and vane, and a scroll compressor that utilizes an orbiting scroll and a fixed scroll.

In addition, research and development of a compressor in an inverter method capable of varying an operating speed of a motor has been actively conducted in a field of the electric compressor. An example of the conventional electric compressor in an inverter method is disclosed in Korea Patent No. 2023-0017728.

According to one example of the conventional electric compressor, an electric compressor 10 includes a housing 11, a compression part 16, an electric motor 17, and an inverter 30. The housing 11 has a motor housing member 12 accommodating the compression part 16 and the electric motor 17, and a discharge housing member 13. The inverter cover 25 is coupled to a shorter wall 12b of the motor housing member 12, and the inverter cover 25 is attached to the shorter wall 12b, thereby partitioning an inverter chamber 26.

The inverter 30 has a circuit board 31 and one or more electric components 32 mounted in the circuit board 31. The electric component 32 is disposed between the circuit board 31 and the shorter wall 12b of the motor housing member 12, and is thermally coupled to the shorter wall 12b. That is, the electric component 32 is come into close contact with the shorter wall 12b of the motor housing member 12 in which a cold suction refrigerant flows, enabling heat dissipation.

To this end, according to the prior art, the electric component 32 is assembled into the motor housing member 12 using a bolt and is soldered to the circuit board 31, or the electric component 32 is pressed toward the motor housing member 12 by soldering the electric component 32 to the circuit board 31 first, and then, pressing it toward the motor housing member 12 using an elastic member such as a clamping and the like. However, there is a problem in that such a method requires an additional part such as a bolt or a clamping for pressing the electric component 32 toward the motor housing member 12, and an assembly process is complex because a threaded groove processing is required in the motor housing member 12. In addition, there is also a problem in that the elastic member such as the clamping cannot evenly press the electric component 32 and thus, a contact failure to the motor housing member 12 occurs and as a result, a heat dissipation characteristic may deteriorate.

### PRIOR ART DOCUMENT

### Patent Document

Korea Patent No. 2023-0017728 (disclosed in Feb. 6, 2023)

### SUMMARY

An object of the present disclosure is to provide an electric compressor of which an inverter cover, an inverter body and a circuit board can be modularized, and capable of improving contactability between a switching element and a motor housing by allowing a pressing member inserted into a boss portion of the inverter body to press another surface, which is an opposite side of one surface on which a switching element of the circuit board is disposed.

The technical problem to be achieved by the present disclosure is not limited to the above-mentioned technical problem, and other technical problems that are not mentioned will be clearly understood by ordinary-skilled persons in the art to which the present disclosure pertains from the following description.

One embodiment is an electric compressor, including: a housing; a compression part configured to compress a refrigerant introduced into the housing; a motor part provided in the housing and configured to drive the compression part; and an inverter part provided on one side of the housing and configured to control the motor part, and the inverter part may include: an inverter cover coupled to one side of the housing; an inverter body fixed inside the inverter cover; and a circuit board seated on the inverter body and allowing one or more elements to be disposed on one surface thereof facing the housing, and the inverter body may include: one or more boss portions protruding from a base surface toward the circuit board, and a pressing member may be inserted into at least one among the one or more boss portions and the pressing member presses another surface which is an opposite side of the one surface of the circuit board.

According to an embodiment, the element may consist of a plurality of switching elements, and the pressing member may press the another surface which is an opposite side of the one surface on which the plurality of switching elements are disposed.

According to an embodiment, the pressing member may be formed of a rubber material, and may be compressively deformed when being inserted into the boss portion.

According to an embodiment, a heat exchange part protruding toward the circuit board may be provided on a partition wall of the housing so as to allow the one or more elements to be in contact with the heat exchange part.

According to an embodiment, the pressing member may be positioned within a region in which the plurality of switching elements are disposed.

According to an embodiment, the electric compressor may further include: a plurality of fastening members penetrating the inverter cover, the inverter body and the circuit board to be fastened to the housing, and the one or more boss portions may be provided close to one among a plurality of second fastening holes of the inverter body allowing the plurality of fastening members to penetrate.

According to an embodiment, every two elements of the plurality of switching elements may pair off, and at least one pressing member may be disposed in every region in which each element pair is disposed.

According to an embodiment, the pressing member may be disposed between every two elements forming each element pair.

According to an embodiment, the pressing member may include a body part contacting another surface of the circuit board and a leg part extending from the body part and inserted into an inner groove of the boss portion.

According to an embodiment, a maximum outside diameter of the leg part before the pressing member is inserted into the boss portion may be greater than a diameter of the inner groove of the boss portion.

According to an embodiment, the leg part may include a pillar portion extending from the body part and a bead portion protruding along a circumferential direction of the pillar portion.

According to an embodiment, in the body part, a diameter d1 of a side meeting the circuit board may be formed smaller than a diameter d2 of a side meeting the boss portion.

According to an embodiment, a through hole may be provided in the pressing member along a longitudinal direction.

According to an embodiment, the inverter body may further include a seating portion protruding from the base surface and allowing the circuit board to be seated thereon and a thermal fusion part extending from the seating portion and thermally fused after penetrating a thermal fusion hole of the circuit board.

According to an embodiment, a height h1 of the boss portion may be lower than a height h2 of the seating portion.

According to an embodiment, before the circuit board is seated on the seating portion, a sum of the height h1 of the boss portion and a height h3 of the pressing member disposed outside the boss portion may be greater than the height h2 of the seating portion.

According to an embodiment, the base surface may include a first base surface relatively close to the inverter cover and a second base surface relatively far from the inverter cover, and each of the boss portion and the seating portion may protrude from the second base surface.

According to the present disclosure, the inverter cover and the circuit board can be modularized through the inverter body, because the inverter body is fixed inside the inverter cover, and a thermal fusion part of the inverter body is thermally fused in the circuit board after penetrating the circuit board.

In addition, it is possible to unify types of the fastening member and reduce a quantity of the fastening member because one type of fastening members penetrate the inverter cover, the inverter body, and the circuit board to be fastened to the housing, thereby becoming capable of reducing expenses and weight.

In addition, the pressing member inserted into the boss portion of the inverter body presses another surface which is an opposite side of one surface on which the switching element of the circuit board is disposed, thereby the switching element is come into close contact with the motor housing, and contactability between the switching element and the motor housing can be increased. As a result, the heat dissipation characteristic of the switching element can be improved. As such, processing of a threaded groove in the motor housing is not required and the assembly process can be simplified, because it is possible to press the switching element evenly toward the motor housing side by using only a pressing member, without any additional part such as a bolt or a clamping.

In particular, before the circuit board is seated on the seating portion of the inverter body, a sum of a height h1 of the boss portion and a height h3 of the pressing member disposed outside the boss portion is formed greater than a height h2 of the seating portion, and therefore, when the circuit board is seated on the seating portion, the pressing member is pressed, and accordingly, the circuit board and the switching element soldered to the circuit board can be definitely pressed toward the motor housing side.

Moreover, a through hole is provided in the pressing member along a longitudinal direction, and thus, when the pressing member is inserted into an inner groove of the boss portion, it is possible to prevent the pressing member from exiting due to an air pressure of the inner groove and the pressing member can be compressed inward (in a direction of the through hole). By doing so, the pressing member cannot get out from the inner groove of the boss portion because of an elastic force in a circumferential direction.

The effects of the embodiments of the present disclosure are not limited to the above-mentioned effects, and it should be understood that the effects of the present disclosure include all effects that could be inferred from the configuration of the present disclosure described in the detailed description of the present disclosure or the appended claims.

### BRIEF DESCRIPTION OF THE DRAWINGS

FIG. 1 is an exploded perspective view of an electric compressor in a state in which an inverter part is separated therefrom.

FIG. 2 is an exploded perspective view in which some components in FIG. 1 are viewed from another perspective.

FIG. 3 is a front view illustrating a state in which an inverter body is separated from FIG. 2.

FIG. 4 is a cross-sectional view illustrating a state in which a pressing member is inserted into an inverter cover and an inverter body which are integrated with each other in FIG. 2.

FIG. 5 is a partial cross-sectional view illustrating a state in which an inverter part in FIG. 1 is assembled.

FIG. 6 is a perspective view when a pressing member shown in FIG. 2 is separated.

FIG. 7 is a plan view of a pressing member in FIG. 6 viewed from above.

FIG. 8A is a front view illustrating a position of a region Ain which each element pair is disposed and a position of a pressing member in contact with another surface in a dotted line by separating a circuit board in FIG. 2.

FIG. 8B is a front view illustrating a position of a region B in which a gate driver is disposed on another surface and a position of a pressing member in contact with another surface in a dotted line by separating a circuit board in FIG. 2.

FIG. 9 is a cross-sectional view illustrating a state in which part of a thermal fusion part of an inverter body is thermally fused.

### DETAILED DESCRIPTION

Hereinafter, exemplary embodiments of the electric compressor of the present disclosure will be described with reference to the accompanying drawings.

In addition, terms used herein are defined in consideration of functions in the present disclosure, and may vary according to user's or operator's intention or practices, and the following embodiments do not limit the scope of the present disclosure, but are merely examples of the components presented in the claims.

In addition, parts irrelevant to the description are omitted for clarity of description, and same or similar components are assigned with the same reference numerals throughout the specification. It will also be understood that the terms “comprises” and “includes” used herein specify the presence of stated elements, but do not preclude the presence or addition of other elements, unless otherwise defined.

In the present specification, regarding an element represented as a “unit”, two or more elements may be combined into one element or one element may be divided into two or more elements according to subdivided functions. In addition, each element described hereinafter may additionally perform some or all of functions performed by another element, in addition to main functions of itself, and some of the main functions of each element may be performed entirely by another component.

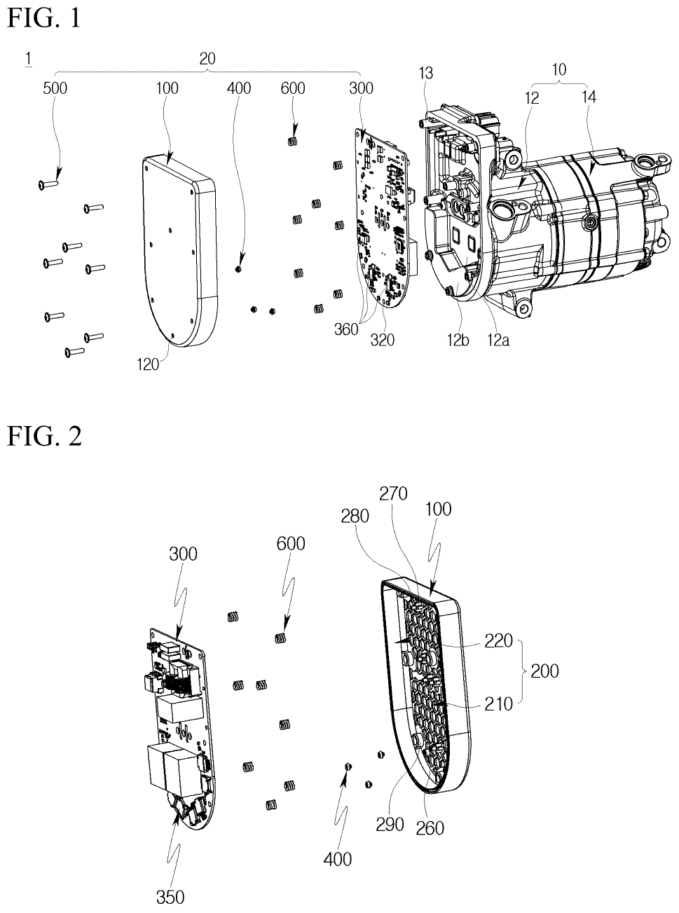

First, the configuration of the electric compressor 1 according to an embodiment of the present disclosure will be briefly described with reference to FIG. 1.

The electric compressor of the present disclosure largely includes a housing 10, a motor part, a compressing part, and an inverter part 20.

The housing 10 forms an exterior of the electric compressor 1, and in this embodiment, the housing 10 consists of a motor housing (a front housing) 12 and a compression housing (a rear housing) 14.

The motor part is provided in the motor housing 12, and provides the compressing part with power for compressing a refrigerant. Although not illustrated, the motor part may include a rotor coupled to a rotary shaft rotatably installed at a center of the motor housing 12 and a stator fixed to the motor housing 12 and disposed radially outside the rotor. Also, the stator may include a stator core and coils wound around the stator core.

The compressing part compresses a refrigerant introduced into the housing 10. In the present embodiment, the compressing part is provided in the compression housing 14 and although not illustrated, may include an orbiting scroll coupled to the rotary shaft through an eccentric bush, and a fixed scroll forming a compression chamber in which the refrigerant is compressed together with the orbiting scroll. As such, since the compressing part is connected to the motor part through the rotary shaft, the rotational force generated by the motor part may be transferred to the orbiting scroll of the compressing part through the rotary shaft. However, it is not limited thereto, and it is apparent that other types of compressing parts may be used.

The inverter part 20 is coupled to one side of the housing 10 which is an opposite side of the compressing part with respect to the motor part. The inverter part 20 is electrically connected to the motor part, supplies power to the motor part by means of power and control signals transmitted from an outside, and controls operations. Specifically, the stator forms an electromagnetic field by power applied from the inverter part 20, and a rotational force for driving the compressing part is generated as the rotor rotates by the electromagnetic field formed by the stator.

At this instance, the motor part, and the inverter part 20 may be electrically connected to each other by a connection pin. Since a three-phase motor is used in this embodiment, three connection pins connected to the three phases, respectively, are provided in order to supply three-phase power from the inverter part 20 to the motor part. The three connection pins are electrically connected to the three-phase coils of the stator, respectively, pass through the motor housing 12 and protrude toward an inside of the inverter part 20. Each of the connection pins protruding to the inside of the inverter part 20 penetrates a circuit board 300 of the inverter part and is electrically connected to the circuit board 300. To this end, through holes may be formed on one side of the front housing 12 and on the circuit board 300 so as to allow the connection pin to pass therethrough.

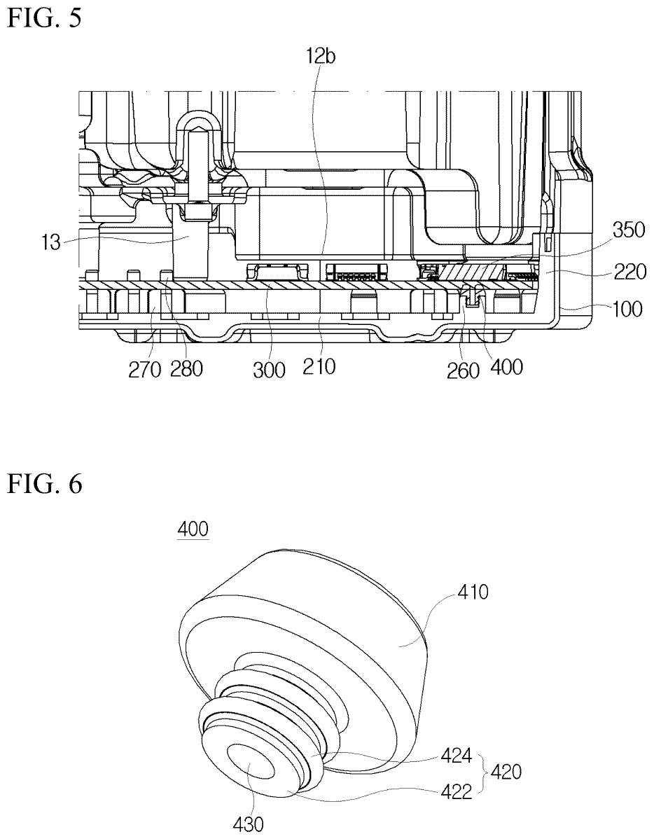

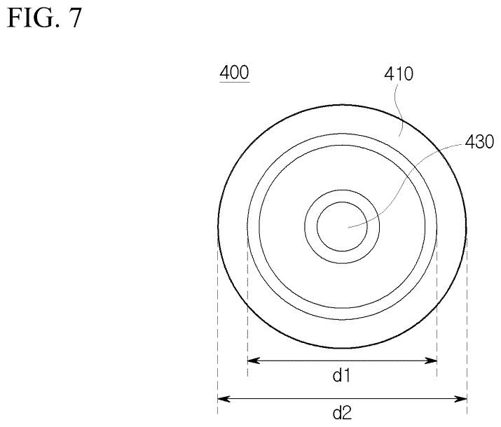

Hereinafter, the inverter part 20 will be described in detail with reference to FIGS. 1 to 8. The inverter part 20 may largely include an inverter cover 100, an inverter body 200, the circuit board 300, a pressing member 400, and a fastening member 500.

The inverter cover 100 is coupled to the housing 10, more particularly, to one side of the motor housing 12, and serves to protect the circuit board 300 from an external impact and the like. The inverter cover 100 is coupled to the motor housing 12 by the fastening member 500 which will be described below, and to this end, a first fastening hole 120 allowing the fastening member 500 to penetrate is formed in the inverter cover 100.

As illustrated in FIG. 2, the inverter body 200 is fixed inside the inverter cover 100 to be integrated with the inverter cover 100. It is preferable that the inverter body 200 is made of a plastic material so as to reduce costs and make it compact. In this case, the inverter cover 100 is made of a metal material, and therefore, the inverter cover 100 and the inverter body 100 can be integrally manufactured through dual injection.

The inverter body 200 has a shape corresponding to the inverter cover 100, and particularly, may be formed with a base surface 210 and a wall surface 220 surrounding the base surface 210 and having a constant height. The wall surface 220 has a shape corresponding to a periphery of the circuit board 300 and includes both a straight line section and a curved line section.

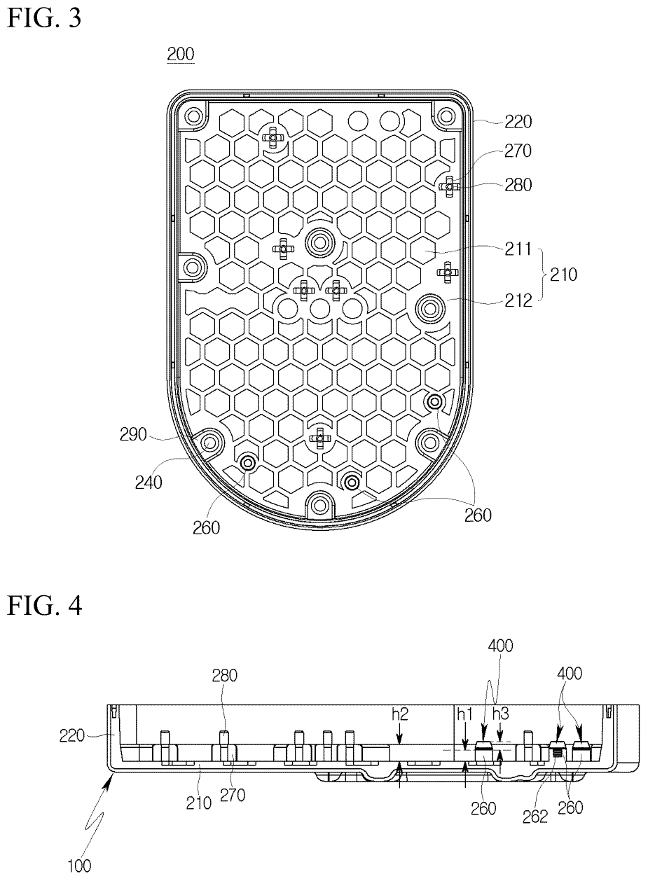

In the present embodiment, the base surface 210 includes a first base surface 211 relatively close to the inverter cover 100, and a second base surface 212 relatively far from the inverter cover 100. Referring to FIGS. 2 and 3, it is seen that the first base surface 211 is formed to be recessed in appropriately a hexagonal shape on the second base surface 212. Accordingly, it is possible to reduce material costs and a weight of the inverter body 200.

A second fastening hole 240 allowing the fastening member 500 to penetrate is formed in the inverter body 200. The second fastening hole 240 of the inverter body is provided at the same position as the first fastening hole 120 to make the second fastening hole 240 be aligned with the first fastening hole 120 so that the fastening member 500 which passes through the first fastening hole 120 can pass through the second fastening hole 240 at the same time.

The circuit board 300 (PCB) is seated on the inverter body 200. One or more elements are disposed on one surface of the circuit board 300 facing the motor housing 12. In the present embodiment, the elements are a plurality of switching elements 350, and are mounted as an SMD (surface-mount-device) type on one surface of the circuit board 300. However, the disclosed technology is not limited thereto, and the plurality of switching elements 350 may be a THT (through-hole-type) switching elements. For example, the switching element 350 may be an IGBT or a MOSFET.

A third fastening hole 320 allowing the fastening member 500 to penetrate is formed in the circuit board 300. The third fastening hole 320 of the circuit board is provided at the same position as the first fastening hole 120 and the second fastening hole 240 to make the third fastening hole 320 be aligned with the first fastening hole 120 and the second fastening hole 240 so that the fastening member 500 which passes through the first fastening hole 120 and the second fastening hole 240 can pass through the third fastening hole 320 at the same time.

As such, the fastening member 500 penetrates the inverter cover 100, the inverter body 200, and the circuit board 300 and is fastened to the motor housing 12. For example, the fastening member 500 may be a fastening bolt. In more detail, the fastening member 500 is fastened to a pillar portion 13 protruding toward the circuit board 300 from the motor housing 12 and supporting one surface of the circuit board 300. As such, the fastening member 500 of one type is fastened to inverter cover 100, the circuit board 300, and the motor housing 12 together, and therefore, it is possible to unify types of the fastening member and reduce the quantity thereof, thereby expenses and weight can be reduced.

In the present embodiment, the fastening member 500 is provided in plural number. In particular, it is preferable that at least one among the plurality of fastening members 500 is disposed closer to a center portion of the inverter cover 100 than an outside thereof. In the present embodiment, eight fastening members 500 are provided, and among them, seven fastening members 500 are disposed outside the inverter cover 100, and one fastening member 500 is disposed at a center portion of the inverter cover 100. However, the disclosed technology is not limited thereto, and the arrangement of the plurality of fastening members 500 may be changed freely. By doing so, at least one fastening member 500 can support the center portion of the inverter cover 100, and a distance between the fastening members 500 is reduced, thereby becoming possible to improve the resonance noise of the inverter cover 100 through increasing a natural frequency. Moreover, the plurality of fastening members 500 are disposed to penetrate the circuit board 300, and thus, it is possible to reduce an outside size of the inverter part.

In the present embodiment, the inverter body 200 includes one or more boss portions 260 protruding toward the circuit board 300 from the base surface 210, and a pressing member 400 is inserted into at least one among the one or more boss portions 260. In the present embodiment, the pressing member 400 is inserted into each of the boss portions 260. At this instance, the pressing member 400 presses another surface which is an opposite side of one surface of the circuit board 300 so that the switching element 350 comes into close contact with the motor housing 12. That is, the pressing member 400 presses another surface opposite the surface on which the plurality of switching elements 350 are disposed. As a result, contactability between the switching element 350 and the motor housing 12 can be increased, and the heat dissipation characteristic of the switching element 350 can be improved.

At this instance, as illustrated in FIGS. 1 and 5, a heat exchange part 12b protruding toward the circuit board 300 so that the heat exchange part 12b can contact the plurality of switching elements 350 may be provided in a partition wall 12a of the motor housing 12. The partition wall 12a of the motor housing 12 divides a space in which the motor part is disposed and a space in which the inverter part 20 is disposed. The space in which the inverter part 20 is disposed is opened and thus, is covered by the inverter cover 100. Accordingly, heat of the switching element 350 is delivered to the heat exchange part 12b, and the heat delivered to the heat exchange part 12b can be effectively cooled by a low-temperature and low pressure refrigerant accommodated on an inside of the heat exchange part 12b.

In addition, a TIM (thermal interface material) may be provided between the switching element 350 and the motor housing 12, more particularly, between the switching element 350 and the heat exchange part 12b of the motor housing, and selection of a kind of the TIM is free. That is, a TIM made of a sheet material, and grease as well as a TIM in a form of liquid may be used.

The pressing member 400 must be made of a material having an excellent electric insulation characteristic because the pressing member 400 directly contacts another surface of the circuit board 300. Therefore, the pressing member 400 may be formed of a rubber material, in particular, an EPDM rubber material. The EPDM rubber has an excellent insulation characteristic, unique flexibility of the rubber, and is advantageous in terms of a price compared to a silicon rubber. In addition, the pressing member 400 may be compressively deformed when the pressing member 400 is inserted into the boss portion 260 because the pressing member 400 is made of the rubber material.

It is preferable that the boss portion 260 and the pressing member 400 are disposed in a region in which the plurality of switching elements 350 are disposed. Here, the region in which the plurality of switching elements 350 are disposed may mean a region between the switching elements 350 disposed on the outermost side. Therefore, the pressing member 400 may effectively press the switching elements 350 toward the motor housing 12.

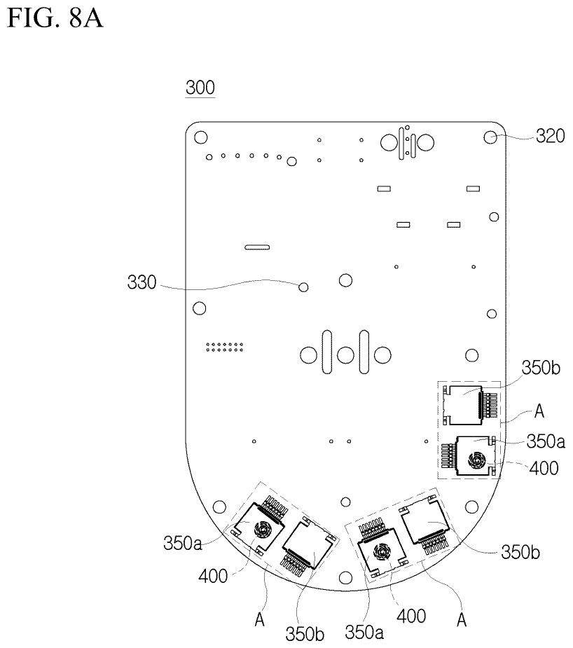

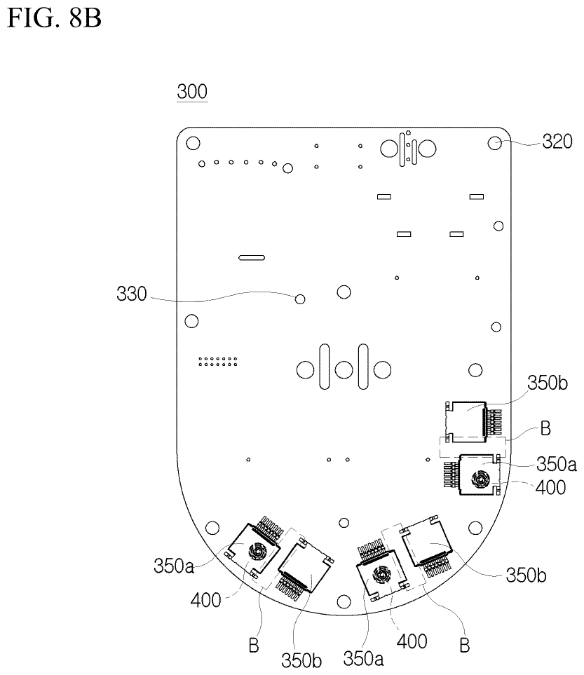

A quantity of the boss portion 260 and a quantity of the pressing member 400 may be changed according to a quantity of the switching elements 350. In the present embodiment, as illustrated in FIG. 8, six switching elements 350 are disposed on one surface of the circuit board 300, and the six switching elements 350 pair off to become three element pairs as every two elements adjacent each other pair off. In more detail, one among the two switching elements of each element pair may correspond to a high side IGBT 350a, and the other thereamong may correspond to a low side IGBT 350b.

In this case, as illustrated in FIG. 8A, it is preferable that at least one pressing member 400 is disposed in each region A in which each element pair is disposed. In the present disclosure, three element pairs are provided in total, and therefore, a minimum three pressing members 400 are provided. Thus, each element pair can be evenly pressed toward the motor housing 12. In FIG. 8A, the region A in which each element pair is disposed and a position of the pressing member 400 contacting another surface is indicated in a dotted line. That is, a position of the plurality of pressing members 400 with respect to the plurality of switching elements 350 are indicated.

In particular, it is preferable that the pressing member 400 is disposed between every two switching elements forming each element pair, that is, between one high side IGBT 350a and one low side IGBT 350b.

However, in case where a gate driver 360 for controlling one element pair is disposed between one high side IGBT 350a and one low side IGBT 350b on another surface of the circuit board 300, the position of the pressing member 400 may lean toward one among the two switching elements forming the element pair so as to avoid the gate driver 360.

In FIG. 8B, a region B in which the gate driver 360 is disposed on another surface of the circuit board 300 and a position of the pressing member 400 contacting another surface is indicated in a dotted line. As illustrated, the gate driver 360 may be disposed between elements forming an element pair, and because of this, the pressing member 400 is disposed to be leaned toward the high side IGBT 350a among two elements forming the element pair so that the pressing member 400 can avoid the gate driver 360.

In particular, it is preferable that the plurality of boss portions 260 is provided close to one among the plurality of second fastening holes 240 of the inverter body 200 which allows the plurality of fastening members 500 to penetrate. This is to facilitate a fastening force of the fastening member 500 to be delivered to the adjacent pressing member 400 through the inverter cover 100 and the inverter body 200 so that the pressing member 400 securely presses the circuit board 300. In more detail, in the present disclosure, three boss portions 260 are disposed such that one boss portion 260 is disposed between two second fastening holes 240 disposed adjacent to each other, but the one boss portion 260 is disposed closer to one among the two adjacent fastening holes 240.

In the present embodiment, the boss portion 260 protrudes from the base surface 210 in a circular shape. At an end of the boss portion 260, an inner groove 262 into which the pressing member 400 is inserted is formed.

The pressing member 400 includes a body part 410 contacting another surface of the circuit board 300, and a leg part 420 extending from the body part 410 and inserted into the inner groove 262 of the boss portion 260.

At this instance, the maximum outside diameter of the leg part 420 before the pressing member 400 is inserted into the boss portion 260 is formed greater than a diameter of the inner groove 262 of the boss portion 260. In the present embodiment, the leg part 420 includes a pillar portion 422 extending from the body part 410, and a bead portion 424 extending along a circumferential direction of the pillar portion 422, and therefore, the maximum outside diameter of the leg part 420 may be an outside diameter of the bead portion 424. However, if the bead portion 424 is not included in the present embodiment, the maximum outside diameter of the leg part 420 may be the outside diameter of the pillar portion 422. As such, the bead portion 424 is provided, and therefore, a groove is formed between the body part 410 and the bead portion 424 or between adjacent bead portions 424, and the assembling efficiency may be improved. That is, it is possible to prevent escape of the pressing member 400 when the pressing member 400 is inserted into the inner groove 262 of the boss portion 260.

In addition, it is preferable that a diameter d1 of a side of the body part 410 meeting the circuit board 300 is formed smaller than a diameter d2 of a side of the body part 410 meeting the boss portion 260. As such, when the diameter d1 meeting the circuit board 300 is small, it is possible to prevent interference between the pressing member 400 and an element disposed on another surface of the circuit board 300 to the fullest.

Athrough hole 430 is provided along a longitudinal direction in the pressing member 400. That is, the through hole 430 extends along the overall longitudinal direction from an end of the body part 410 to an end of the leg part 420. As such, the through hole 430 is provided in the pressing member 400, it is possible to prevent separation of the pressing member 400 due to an air pressure of the inner groove when the pressing member 400 is inserted into the inner groove 262 of the boss portion 260, and to allow the pressing member 400 to be compressed inward (in a direction of the through hole) when the pressing member 400 is inserted into the inner groove 262. By doing so, the pressing member 400 cannot leave the inner groove 262 of the boss portion 260 easily because of the elastic force in a circumferential direction.

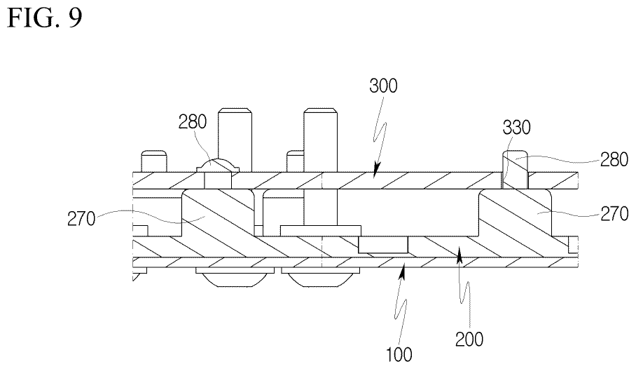

The inverter body 200 further includes a seating portion 270 protruding from the base surface 210 and on which the circuit board 300 is seated, and a thermal fusion part 280 extending from the seating portion 270 and penetrating the thermal fusion hole 330 of the circuit board 300 to be thermally fused therein. The inverter body 200 is made of a plastic material, and thus, thermal fusion can be made in the inverter body 200. In FIG. 9, a state in which the thermal fusion part 280 penetrates the thermal fusion hole 330 of the circuit board and is thermally fused is illustrated. Before the thermal fusion part 280 is thermally fused, the thermal fusion part 280 serves to guide the circuit board 300, and after the thermal fusion part 280 is thermally fused, the thermal fusion part 280 serves to fix a position of the circuit board 300 inside the inverter body 200 as the thermal fusion part 280 is fixed in the thermal fusion hole 330 of the circuit board 300.

In order to secure a space of the circuit board 300 for arranging the elements, it is preferable that a diameter of the thermal fusion hole 330 of the circuit board 300 is smaller than a diameter of the third fastening hole 320. In the present embodiment, the thermal fusion hole 330 is formed as a through hole penetrating the circuit board, however, depending on cases, the thermal fusion hole 330 may be formed as a cut-hole cut inward from an outer periphery of the circuit board.

As the circuit board 300 is seated on the seating portion 270, the circuit board 300 is supported in a state of being spaced apart from the base surface 210 of the inverter body 200. With this configuration, unevenness of the circuit board due to the interference between the inverter body 200 and the circuit board 300 can be prevented and the circuit board can be seated reliably on the inverter body 200.

The seating portion 270 and the thermal fusion part 280 may be provided in plural number, and as illustrated in FIG. 3, in the present embodiment, seven seating portions 270 and seven thermal fusion parts 280 are provided. Each of the seating portions 270 have the same height so that the circuit board 300 can be seated stably on the seating portions 270. In the present embodiment, the seating portion 270 is illustrated to have a cross-shape, but is not limited thereto, and may have various shapes such as a circular pillar shape, a quadrangular pillar shape, and the like.

The height h1 of the boss portion 260 is formed lower than the height h2 of the seating portion 270. At this instance, both the boss portion 260 and the seating portion 270 may protrude from the second base surface 212. As such, both the boss portion 260 and the seating portion 270 protrude from the second base surface 212 which is higher among the base surface 210 of the inverter body so that a protrusion height of the boss portion 260 and the seating portion 270 can be minimized, and as a result, stability of the protrusion structure can be improved while reducing a material expense.

The inverter body 200 is integrally fixed inside the inverter cover 100, and a position of the circuit board 300 is fixed through thermal fusion of the inverter body 200, therefore, the inverter cover 100 and the circuit board 300 can be modularized through the inverter body 200.

By performing thermal fusion in a state in which the circuit board 300 is seated on the inverter body 200 so as to modularize the inverter cover 100, the inverter body 200, and the circuit board 300 as one inverter module, the inverter module can be fastened to the motor housing 12 through the fastening member 500. As a result, the assembling efficiency of the inverter part 20 can be improved. A seal for sealing may be disposed between the inverter module and the motor housing 12.

In particular, before the circuit board 300 is seated on the seating portion 270, a sum of the height h1 of the boss portion 260 and the height h3 of the pressing member 400 disposed outside the boss portion 260 may be formed greater than the height h2 of the seating portion 270. In the present embodiment, the height h3 of the pressing member 400 disposed outside the boss portion 260 corresponds to a height of the body part 410. Therefore, when the circuit board 300 is seated on the seating portion 270, the pressing member 400 is pressed, and as a result, the circuit board 300 and the switching element 350 soldered to the circuit board 300 can be securely compressed toward the motor housing 12 when the inverter module is fastened to the motor housing 12.

In addition, according to an embodiment, the inverter body 200 may further include a protrusion 290 protruding from the base surface 210 while surrounding the second fastening hole 240 so that the fastening member 500 can penetrate the protrusion 290 while supporting the circuit board 300. The protrusion 290 has a shape of a hollow pillar, and an elastic member 600 for connecting the inverter cover 100 and a ground of the circuit board 300 may be disposed inside the protrusion 290. The elastic member 600 made of a metal material has both ends, each of which contacts the inverter cover 100 and the circuit board 300, respectively, and a position of the elastic member 600 is constrained between the inverter cover 100 and the circuit board 300, and therefore, the elastic member 600 cannot be separated from the position without requiring a separate fixing member. The elastic member 600 is illustrated as a coil spring as an example. As such, the elastic member 600 can connect the inverter cover 100 and the ground of the circuit board 300, and therefore, no additional ground means for the circuit board 300 is required. To this end, a copper foil (not illustrated) surrounding the third fastening hole 320 and allowing the elastic member 600 to contact may be further provided in the circuit board 300. The copper foil means a thin copper foil, and may have a ring shape which surrounds the third fastening hole 320.

Further, the fastening member 500 penetrates an inside of the elastic member 600 and fastens the inverter cover 100 together with the circuit board 300 to the motor housing 12, and the elastic member 600 serves to support the circuit board 300, thereby a quantity of the fastening member 500 can be reduced and noise and vibration can be absorbed.

As described above, both the elastic member 600 and the pressing member 400 press the circuit board 300 which is something in common between the elastic member 600 and the pressing member 400, however, the elastic member 600 contacts the inverter cover 100 formed of the metal material, while the pressing member 400 contacts the inverter body 200 formed of a non-metal material (a resin material) which is a difference between the elastic member 600 and the pressing member 400. Moreover, the elastic member 600 is formed of a metal material (a conductive material), therefore, becomes electrically conductive (grounded) in contact with the copper foil of the circuit board 300, while the pressing member 400 is formed of a non-conductive material, which is a rubber, and is not electrically conductive with the circuit board 300. In addition, the elastic member 600 is fastened together with the fastening member 500, while the pressing member 400 is formed in a position corresponding to the switching element 350, rather than a position to which the fastening member 500 is fastened, which is a difference between the elastic member 600 and the pressing member 400.

The present disclosure is not limited to the above-described specific embodiments and descriptions, and various modifications may be made by those skilled in the art without departing from the gist of the present disclosure claimed in the claims. Such variations are within the protection scope of the present disclosure.

### REFERENCE NUMERALS

1: elastic compressor
10: housing
12: motor housing
12a: partition wall
12b: heat exchange part
13: pillar portion
14: compression housing
20: inverter part
100: inverter cover
120: first fastening hole
200: inverter body
210: base surface
211: first base surface
212: second base surface
220: wall surface
240: second fastening hole
260: boss portion
262: inner groove
270: seating portion
280: thermal fusion part
290: protrusion
300: circuit board
320: third fastening hole
330: thermal fusion hole
350: switching element
350a: high side IGBT
350b: low side IGBT
360: gate driver
400: pressing member
410: body part
420: leg part
422: pillar portion
424: bead portion
430: through hole
500: fastening member
600: elastic member

What is claimed is:

1. An electric compressor, comprising:
a housing;
a compression part configured to compress a refrigerant introduced into the housing;
a motor part provided in the housing and configured to drive the compression part; and
an inverter part provided on one side of the housing and configured to control the motor part,
wherein the inverter part further comprises:
an inverter cover coupled to one side of the housing;
an inverter body fixed inside the inverter cover; and
a circuit board seated on the inverter body and allowing one or more elements to be disposed on a first surface thereof facing the housing,
wherein the inverter body further comprises:
one or more boss portions protruding from a base surface toward the circuit board, and wherein a pressing member is inserted into at least one among the one or more boss portions and the pressing member presses a second surface which is an opposite side of the first surface of the circuit board.

2. The electric compressor of claim 1, wherein the one or more elements comprises a plurality of switching elements, and wherein the pressing member presses the second surface which is the opposite side of the first surface on which the plurality of switching elements is disposed.

3. The electric compressor of claim 1, wherein the pressing member is formed of a rubber material, and is compressively deformed when inserted into the one or more boss portions.

4. The electric compressor of claim 1, wherein a heat exchange part protruding toward the circuit board is provided on a partition wall of the housing to allow the one or more elements to be in contact with the heat exchange part.

5. The electric compressor of claim 2, wherein the pressing member is positioned within a region in which the plurality of switching elements is disposed.

6. The electric compressor of claim 5, further comprising:
a plurality of fastening members penetrating the inverter cover, the inverter body and the circuit board to be fastened to the housing, wherein the one or more boss portions are provided close to one among a plurality of second fastening holes of the inverter body allowing the plurality of fastening members to penetrate.

7. The electric compressor of claim 5, wherein every two of the plurality of switching elements pairs off, and wherein there is a plurality of pressing members and at least one of the plurality of pressing members is disposed in the region in which each pair of the plurality of switching elements is disposed.

8. The electric compressor of claim 7, wherein the at least one of the plurality of pressing members is disposed between the two of the plurality of switching elements forming each pair of the plurality of switching elements.

9. The electric compressor of claim 1, wherein the pressing member includes a body part contacting the second surface of the circuit board and a leg part extending from the body part and inserted into an inner groove of the one or more boss portions.

10. The electric compressor of claim 9, wherein a maximum outside diameter of the leg part before the pressing member is inserted into the one or more boss portions is greater than a diameter of the inner groove of the one or more boss portions.

11. The electric compressor of claim 10, wherein the leg part includes a pillar portion extending from the body part and a bead portion protruding along a circumferential direction of the pillar portion.

12. The electric compressor of claim 9, wherein in the body part, a diameter d1 of a side meeting the circuit board is formed smaller than a diameter d2 of a side meeting the one or more boss portions.

13. The electric compressor of claim 1, wherein a through hole is provided in the pressing member along a longitudinal direction.

14. The electric compressor of claim 1, wherein the inverter body further comprises a seating portion protruding from the base surface and allowing the circuit board to be seated thereon and a thermal fusion part extending from the seating portion and thermally fused after penetrating a thermal fusion hole of the circuit board.

15. The electric compressor of claim 14, wherein a height h1 of the one or more boss portions is lower than a height h2 of the seating portion.

16. The electric compressor of claim 15, wherein before the circuit board is seated on the seating portion, a sum of the height h1 of the one or more boss portions and a height h3 of the pressing member disposed outside the one or more boss portions is greater than the height h2 of the seating portion.

17. The electric compressor of claim 14, wherein the base surface includes a first base surface and a second base surface further from the inverter cover than the first base surface, and wherein each of the one or more boss portions and the seating portion protrudes from the second base surface.
